(19) United States
(12) Patent Application Publication
(10) Pub. No.: US 2009/0224787 A1
(43) Pub. Date: Sep. 10, 2009

(54) PROBING APPARATUS FOR MEASURING ELECTRICAL PROPERTIES OF INTEGRATED CIRCUIT DEVICES ON SEMICONDUCTOR WAFER

(75) Inventors: LI PENG CHANG, HSINCHU CITY (TW); KUO YIN HUANG, TAITUNG COUNTY (TW); JUNG CHUN LIN, HSINCHU CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 12/043,111

(22) Filed: Mar. 5, 2008

(51) Int. Cl. G01R 31/02

(52) U.S. Cl. 324/758

(57) ABSTRACT

A probing apparatus comprises a wafer chuck configured to receive a semiconductor wafer having a plurality of integrated circuit devices and test keys configured to monitor the fabrication quality of the integrated circuit devices, a carrier configured to receive a probe card having a plurality of probe needles configured to contact the test keys of the semiconductor wafer and collect electrical information of the integrated circuit devices, and an angular adjusting module configured to adjust the angle between the probe card and the semiconductor wafer by rotating the semiconductor wafer.

### BACKGROUND OF THE INVENTION

(A) Field of the Invention

The present invention relates to a probing apparatus for measuring electrical properties of integrated circuit devices on a semiconductor wafer, and more particularly, to a probing apparatus having a holder configured to rotate a semiconductor wafer around a probe card configured to measure electrical properties of integrated circuit devices on the semiconductor wafer.

(B) Description of the Related Art

Generally, it is necessary to measure electrical properties of integrated circuit devices at the wafer level to verify that the integrated circuit device satisfies the product specification. Integrated circuit devices with all electrical properties satisfying specifications are selected to continue through the subsequent packaging process, while other devices are discarded to avoid additional packaging cost. Another electrical property test is performed on the integrated circuit device after the packaging process is completed to identify and scrap unsatisfactory devices so as to increase product yield. In other words, the integrated circuit device undergoes several tests during the manufacturing process. Apparatus known as wafer-probing machines have been used to electrically measure electrical properties of integrated circuit devices on semiconductor wafers. In such apparatus, a probing needle is usually brought into contact with a target portion (test key) of the integrated circuit device to collect electrical information or data on one or more electrical properties of the integrated circuit device.

However, the conventional probing machine only allows the probing needle to contact the test key along one direction, which limits the circuit designer to position the test key only along a certain direction. If the test keys are designed to be positioned along two perpendicular directions, the semiconductor wafer must undergo two individual testing processes, which is time-consuming in cases where the test is performed at high temperature since the operator can not rotate the semiconductor wafer by hand until the temperature has cooled to room temperature, which may be time-consuming.

### SUMMARY OF THE INVENTION

One aspect of the present invention provides a probing apparatus having a holder configured to rotate a semiconductor wafer around a probe card configured to measure electrical properties of integrated circuit devices on the semiconductor wafer.

A probing apparatus according to this aspect of the present invention comprises a wafer chuck configured to receive a semiconductor wafer having a plurality of integrated circuit devices and test keys configured to monitor the fabrication quality of the integrated circuit devices, a carrier configured to receive a probe card having a plurality of probe needles configured to contact the test keys of the semiconductor wafer to collect electrical information of the integrated circuit devices, and an angular adjusting module configured to adjust the angle between the probe card and the semiconductor wafer by rotating the semiconductor wafer.

### BRIEF DESCRIPTION OF THE DRAWINGS

The objectives and advantages of the present invention will become apparent upon reading the following description and upon reference to the accompanying drawings in which:

FIG. 1 to FIG. 8 illustrate a probing apparatus according to one embodiment of the present invention; and

FIG. 9 to FIG. 12 illustrate the operation of the probing apparatus according to one embodiment of the present invention.

### DETAILED DESCRIPTION OF THE INVENTION

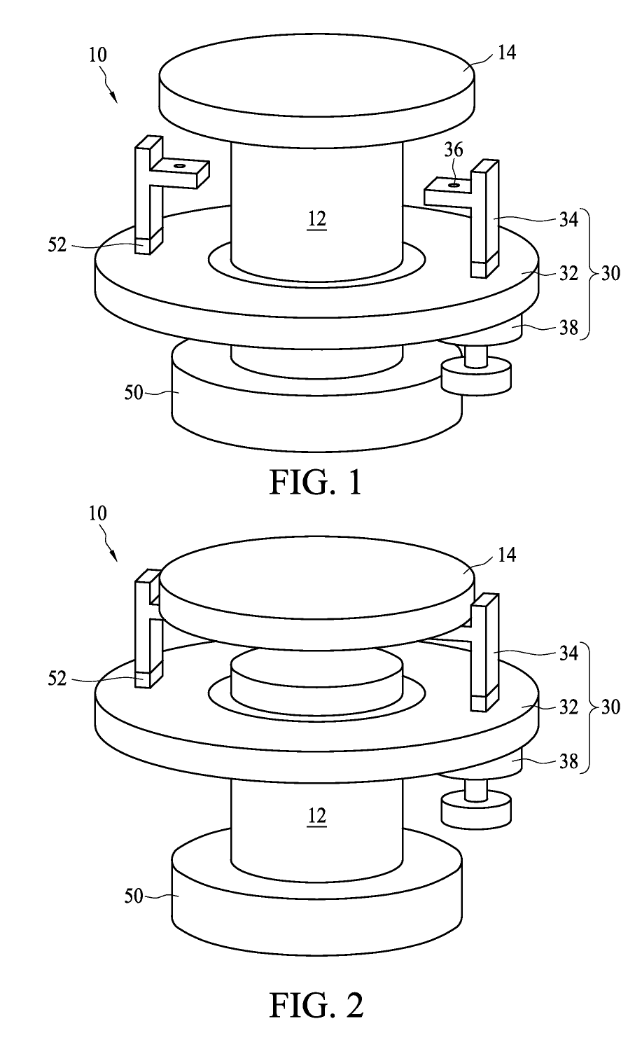

FIG. 1 to FIG. 8 illustrate a probing apparatus 10 according to one embodiment of the present invention. Referring to FIG. 1 and FIG. 2, the probing apparatus 10 comprises a wafer chuck 12 configured to receive a semiconductor wafer 14, a carrier 20 configured to receive a probe card 26 shown in FIG. 4, and an angular adjusting module 30 configured to adjust the angle between the probe card 26 and the semiconductor wafer 14 by rotating the semiconductor wafer 14.

Referring to FIG. 1 and FIG. 2, the angular adjusting module 30 includes a ring-shaped member 32, a driving device 52 positioned on the ring-shaped member 32 and a plurality of braces 34 positioned on the driving device 52. The braces 34 are configured to hold a bottom surface of the semiconductor wafer 14 by vacuum force via an opening 36 or configured to clip a peripheral of the semiconductor wafer 14. In particular, the wafer chuck 12 may include a heating member and a cooling member configured to adjust the temperature of the semiconductor wafer 14 positioned on the wafer chuck 12 by vacuum force.

Referring to FIG. 1 and FIG. 2, the probing apparatus 10 may include an elevator 50 configured to move the semiconductor wafer 14 vertically. For example, the wafer chuck 12 is disposed on the elevator 50, and the elevator 50 is configured to move the wafer chuck 12 vertically such that the semiconductor wafer 14 on the wafer chuck 12 can be moved vertically. Furthermore, the elevator 50 may be optionally configured to move the angular adjusting module 30 vertically such that the semiconductor wafer 14 can be lifted from the wafer chuck 12 vertically by the braces 34.

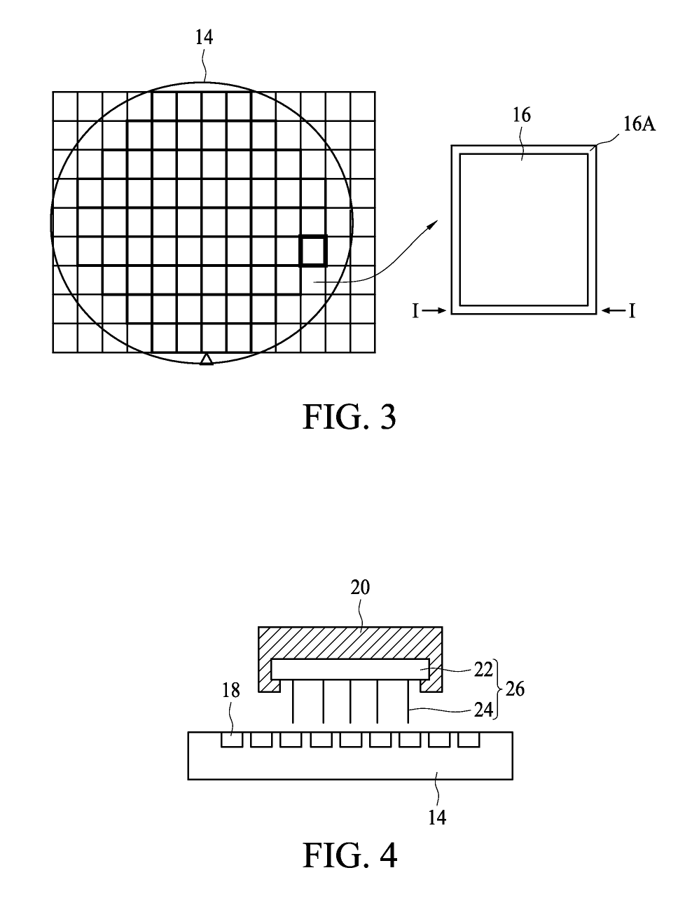

Referring to FIG. 3. The semiconductor wafer 14 includes a plurality of integrated circuit devices 16 such as main dies and a plurality of test keys 18 configured to monitor the fabrication quality of the integrated circuit devices 16. The test keys 18 are positioned at a scribe line 16A surrounding the integrated circuit devices 16, i.e., positioned on the semiconductor wafer 14 in a two-dimensional manner.

Referring to FIG. 4, which is a cross-sectional view of FIG. 3 along a cross-sectional line I-I. The probe card 26 includes a circuit board 22 and a plurality of probe needles 24 configured to contact the test keys 18 of the semiconductor wafer 14 to collect electrical information of the integrated circuit devices 16. In particular, the angular adjusting module 30 is configured to rotate the semiconductor wafer 14 around the probe card 20 substantially by 90 degrees.

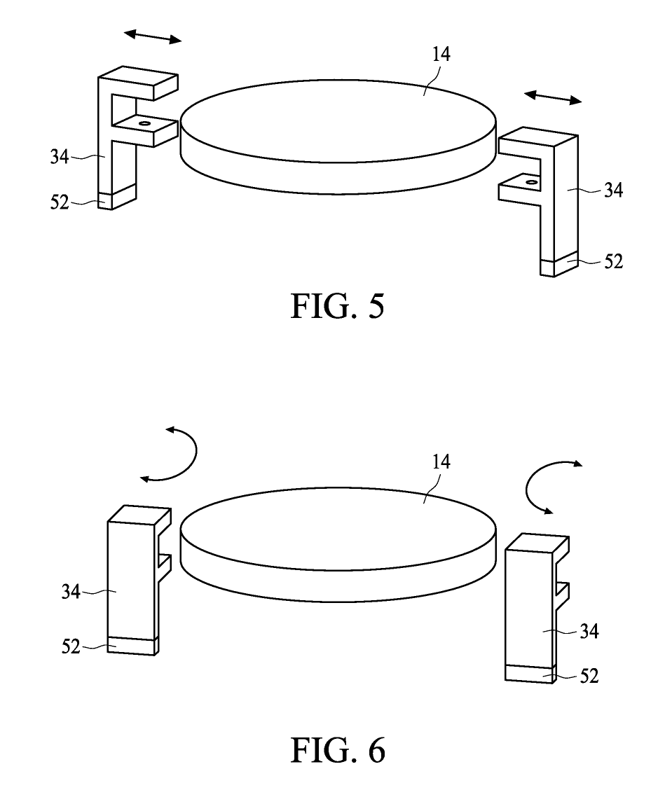

Referring to FIG. 5 and FIG. 6, the braces 34 of the angular adjusting module 30 may be laterally removed or rotated by the driving device 52 such that the braces 34 can hold a bottom surface of the semiconductor wafer 14. In addition, the braces 34 can also be optionally configured to clip a peripheral of the semiconductor wafer 14, instead of holding the bottom surface of the semiconductor wafer 14.

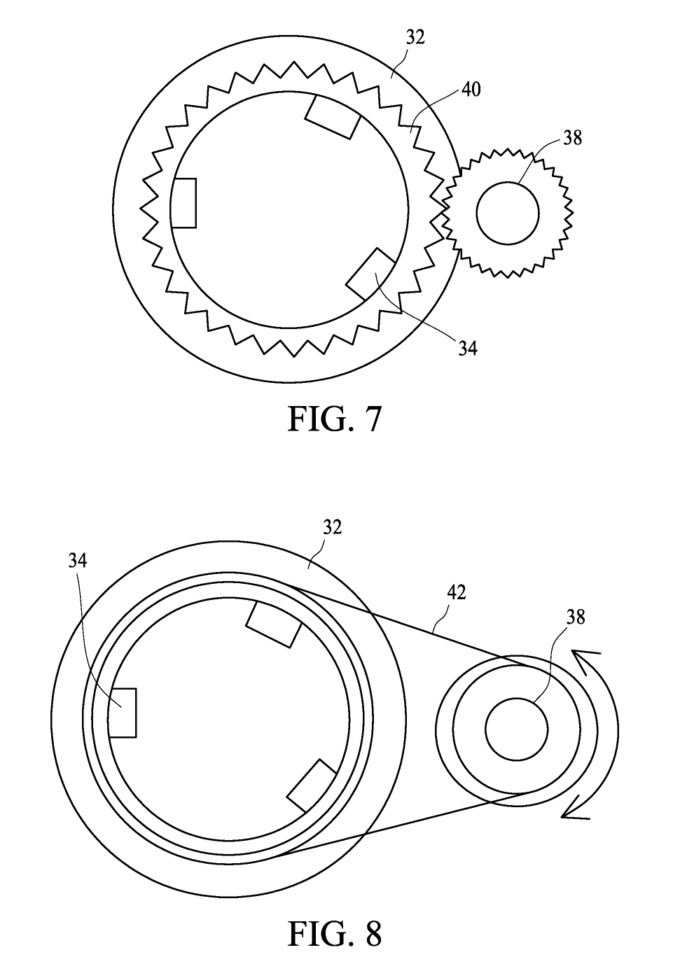

Referring to FIG. 7 and FIG. 8, the angular adjusting module 30 further includes a driving device 38 such as a step motor configured to rotate the ring-shaped member 32 such that the semiconductor wafer 14 can be rotated around the probe card 20 substantially by 90 degrees as the semiconductor wafer 14 is lifted from the wafer chuck 12 by braces 34. For example, the driving device 38 may be configured to rotate the ring-shaped member 32 by gears 40 or by a belt 42.

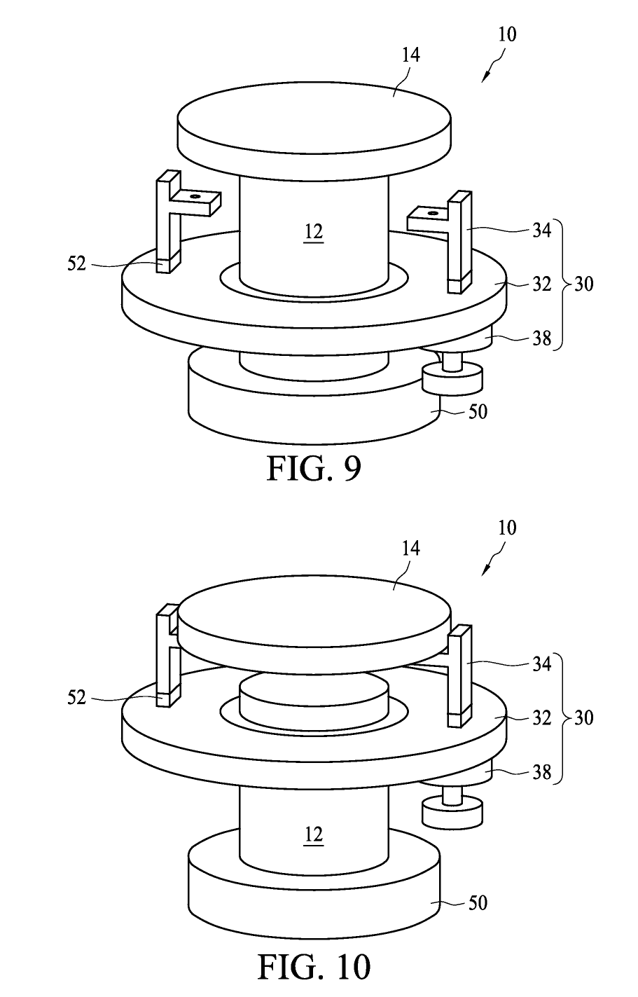

FIG. 9 to FIG. 12 illustrate the operation of the probing apparatus 10 according to one embodiment of the present invention. First, the semiconductor wafer 14 is positioned on the wafer chuck 12 and the probe card 26 uses the probe needles 24 to contact the test keys 18 positioned in one direction (for example, in the X-axis direction) to collect electrical information of the integrated circuit devices 16. Subsequently, as the probe card 26 completes the information collection from the test keys 18 in the X-axis direction, the elevator 50 moves the wafer chuck 12 vertically downward such that the semiconductor wafer 14 is lifted from the wafer chuck 12 by the braces 34 holding the bottom surface of the semiconductor wafer 14, as shown in FIG. 10. In addition, the semiconductor wafer 14 can be lifted from the wafer chuck 12 by using the driving device 52 to elevate the braces 34 upward to hold the bottom surface of the semiconductor wafer 14.

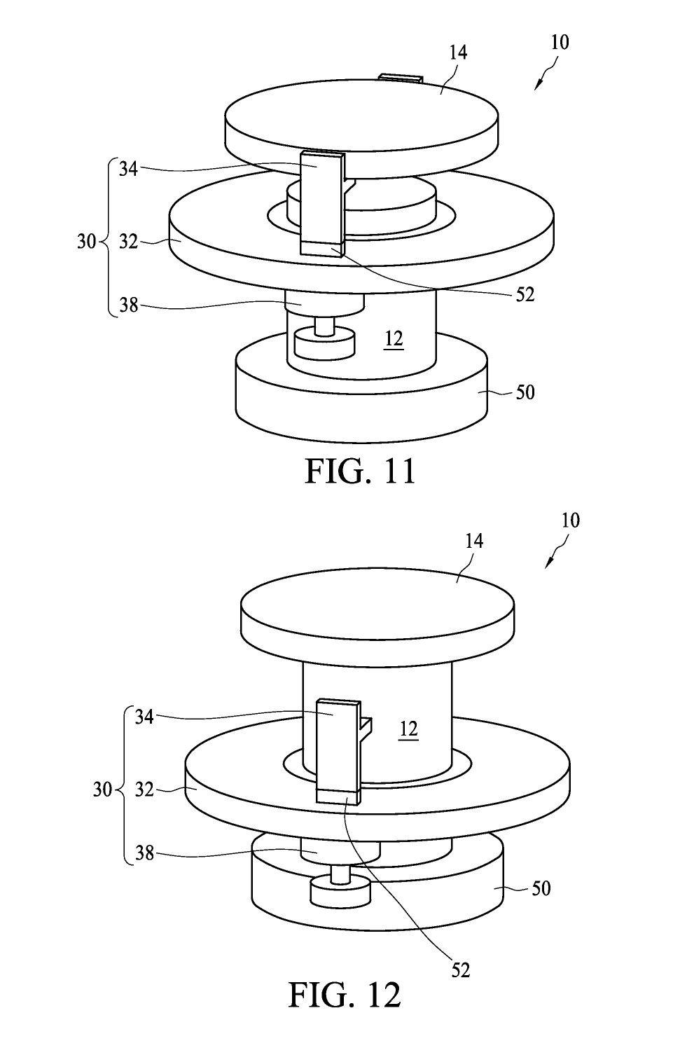

Referring to FIG. 11, the driving device 38 of the angular adjusting module 30 rotates the semiconductor wafer 14 around the probe card 26 substantially by 90 degrees such that the other test keys 18 on the Y-axis direction are aligned to the probe needles 24 of the probe card 26, and the elevator 50 then moves the wafer chuck 12 vertically upward such that the semiconductor wafer 14 is disposed on the wafer chuck 12 and the braces 34 release the semiconductor wafer 14, as shown in FIG. 12. In addition, the semiconductor wafer 14 can be placed on the wafer chuck 12 by using the driving device 52 to move the braces 34 downward to release the semiconductor wafer 14.

Subsequently, the probe card 26 uses the probe needles 24 to contact the test keys 18 positioned in the Y-axis direction to collect electrical information of the integrated circuit devices 16. Consequently, the probing apparatus 10 can collect electrical information of the integrated circuit devices 16 via the test keys 18 arranged in a two-dimensional manner with the semiconductor wafer 14 undergoing a single test process.

The above-described embodiments of the present invention are intended to be illustrative only. Numerous alternative embodiments may be devised by those skilled in the art without departing from the scope of the following claims.

What is claimed is:

1. A probing apparatus, comprising:
a wafer chuck configured to receive a semiconductor wafer having a plurality of integrated circuit devices and test keys configured to monitor the fabrication quality of the integrated circuit devices;
a carrier configured to receive a probe card having a plurality of probe needles configured to contact the test keys of the semiconductor wafer to collect electrical information of the integrated circuit devices; and
an angular adjusting module configured to adjust the angle between the probe card and the semiconductor wafer by rotating the semiconductor wafer.

2. The probing apparatus of claim 1, wherein the wafer chuck includes a heating member and a cooling member configured to adjust the temperature of the semiconductor wafer.

3. The probing apparatus of claim 1, further comprising an elevator configured to move the semiconductor wafer vertically.

4. The probing apparatus of claim 3, wherein the wafer chuck is disposed on the elevator configured to move the wafer chuck vertically.

5. The probing apparatus of claim 1, wherein the test keys are positioned on the semiconductor wafer in a two-dimensional manner, and the angular adjusting module is configured to rotate the semiconductor wafer.

6. The probing apparatus of claim 5, wherein the angular adjusting module is configured to rotate the semiconductor wafer substantially by 90 degrees.

7. The probing apparatus of claim 1, wherein the angular adjusting module includes a ring-shaped member and a plurality of braces positioned on the ring-shaped member.

8. The probing apparatus of claim 7, further comprising a driving device disposed on the ring-shaped member and configured to move the braces.

9. The probing apparatus of claim 7, wherein the braces are configured to hold a bottom surface of the semiconductor wafer by a vacuum force.

10. The probing apparatus of claim 7, wherein the braces are configured to clip a peripheral of the semiconductor wafer.

11. The probing apparatus of claim 7, wherein the angular adjusting module further includes a driving device configured to rotate the ring-shaped member.

12. The probing apparatus of claim 11, wherein the driving device is a step motor.

13. The probing apparatus of claim 11, wherein the driving device rotates the ring-shaped member by gears.

14. The probing apparatus of claim 11, wherein the driving device rotates the ring-shaped member by a belt.

15. The probing apparatus of claim 8, wherein the braces are configured to move to a bottom surface of the semiconductor wafer by a rotation operation.

16. The probing apparatus of claim 8, wherein the braces are configured to move to a bottom surface of the semiconductor wafer by a lateral moving operation.

17. The probing apparatus of claim 1, wherein the probe needles of the probe card are positioned in a one-dimensional manner.

18. The probing apparatus of claim 1, wherein the angular adjusting module is configured to position the probe needles arranged in a one-dimensional manner to contact a portion of the test keys positioned in a two-dimensional manner.
